(19) United States
(12) Patent Application Publication
(10) Pub. No.: US 2008/0289577 A1
(43) Pub. Date: Nov. 27, 2008

(54) Workpiece processing apparatus

(75) Inventors: Ryuichi Iwasaki, Wakayama-shi (JP); Hirofumi Mankawa, Wakayama-shi (JP); Shigeru Masuda, Wakayama-shi (JP); Hirofumi Hayashi, Wakayama-shi (JP); Masaaki Mike, Wakayama-shi (JP)

Correspondence Address: JORDAN AND HAMBURG LLP, 122 EAST 42ND STREET, SUITE 4000, NEW YORK, NY, 10168, US

(73) Assignee: NORITSU KOKI CO., LTD., Wakayama-shi (JP)

(21) Appl. No.: 12/152,039

(22) Filed: May 12, 2008

(30) Foreign Application Priority Data
May 25, 2007 (JP) 2007-139174

(51) Int. Cl. C23C 16/00

(52) U.S. Cl. 118/729

(57) ABSTRACT

A workpiece processing apparatus S, which comprises: a plasma generator unit 6 including a plasma generation section 18 operable to plasmatize a given gas supplied thereto, and emit the plasmatized gas therefrom; and a transport mechanism 2 adapted to support a target workpiece W in a position beneath the plasma generation section 18, wherein the plasmatized gas is emitted onto the workpiece W to carry out a given processing. The workpiece processing apparatus S further includes a setup frame 4 adapted to set up the plasma generator unit 6 to allow the plasma generation section 18 to be located over the workpiece. The plasma generator unit 6 is mounted to the setup frame 4 in a manner capable of being drawn out of a setup position where the plasma generation section 18 is positioned over the workpiece W, in a horizontal direction.

### BACKGROUND OF THE INVENTION

1. Field of the Invention

The present invention relates to a workpiece processing apparatus designed to emit a plasma onto a target workpiece so as to subject the workpiece to a given processing.

2. Description of the Related Art

Heretofore, there has been known a workpiece processing apparatus designed to emit a plasma onto a target workpiece, such as a semiconductor substrate, so as to carry out a given processing for a surface of the workpiece, such as an organic-contaminant removal processing, a surface modification processing, an etching processing, a thin-film formation processing, or a thin-film removal processing. One example of this type of workpiece processing apparatus is disclosed, for example, in JP 2003-197397A (hereinafter referred to as “Patent Publication 1”). The workpiece processing apparatus disclosed in the Patent Publication 1 comprises a plasma generation section including a plasma generation nozzle operable to plasmatize a given gas supplied thereto, wherein the gas plasmatized by the plasma generation nozzle is emitted onto a target workpiece to subject the target workpiece to the above various processings. In the workpiece processing apparatus, a table having a moving mechanism is installed below the plasma generation section, and a target workpiece is placed on the table and set at a given position for receiving the emitted plasma.

The above workpiece processing apparatus involves a problem that, due to the arrangement where the table is installed below the plasma generation section, the table obstructs a maintenance task, such as replacement of the plasma generation nozzle or inspection of the plasma generation section, and makes it hard to perform the maintenance task.

### SUMMARY OF THE INVENTION

In view of the above problem, it is an object of the present invention to provide a workpiece processing apparatus capable of facilitating a maintenance task for a plasma generation section.

In order to achieve this object, the present invention provides a workpiece processing apparatus which comprises: a plasma generator unit including a plasma generation section operable to plasmatize a given gas supplied thereto, and emit the plasmatized gas therefrom; and a support section adapted to support a target workpiece in a position beneath the plasma generation section, wherein the plasmatized gas is emitted onto the workpiece to carry out a given processing. The workpiece processing apparatus further includes a setup frame adapted to set up the plasma generator unit to allow the plasma generation section to be located over the workpiece. The plasma generator unit is mounted to the setup frame in a manner capable of being drawn out of a setup position where the plasma generation section is positioned over the workpiece, in a horizontal direction.

In the workpiece processing apparatus of the present invention, the plasma generator unit can be drawn out of the setup position where the plasma generation section is positioned over the workpiece, in the horizontal direction. Thus, after drawing the plasma generator unit to a position where the plasma generation section is located out of the setup position over the support section which supports the workpiece, a maintenance task for the plasma generation section can be performed without being obstructed by the support section. This makes it possible to facilitate the maintenance task for the plasma generation section.

These and other objects, features and advantages of the invention will become more apparent upon reading the following detailed description along with the accompanying drawings.

### BRIEF DESCRIPTION OF THE DRAWINGS

FIG. 1 is a perspective view showing a general structure of a workpiece processing apparatus according to one embodiment of the present invention.

FIG. 2 is a perspective view showing a plasma generator unit of the workpiece processing apparatus illustrated in FIG. 1.

FIG. 3 is a fragmentary perspective view showing the workpiece processing apparatus illustrated in FIG. 1, in a state when an engagement member of a setup frame and a roller member of the plasma generator unit are engaged with each other.

FIG. 4 is an enlarged view showing a region where the engagement member and the roller member are engaged with each other, in FIG. 3.

FIG. 5 is a fragmentary perspective view corresponding to FIG. 3, which shows a state after the engagement between the engagement member of the setup frame and the roller member of the plasma generator unit are released.

### DESCRIPTION OF THE PREFERRED EMBODIMENTS

With reference to the drawings, the present invention will now be specifically described based on an embodiment thereof.

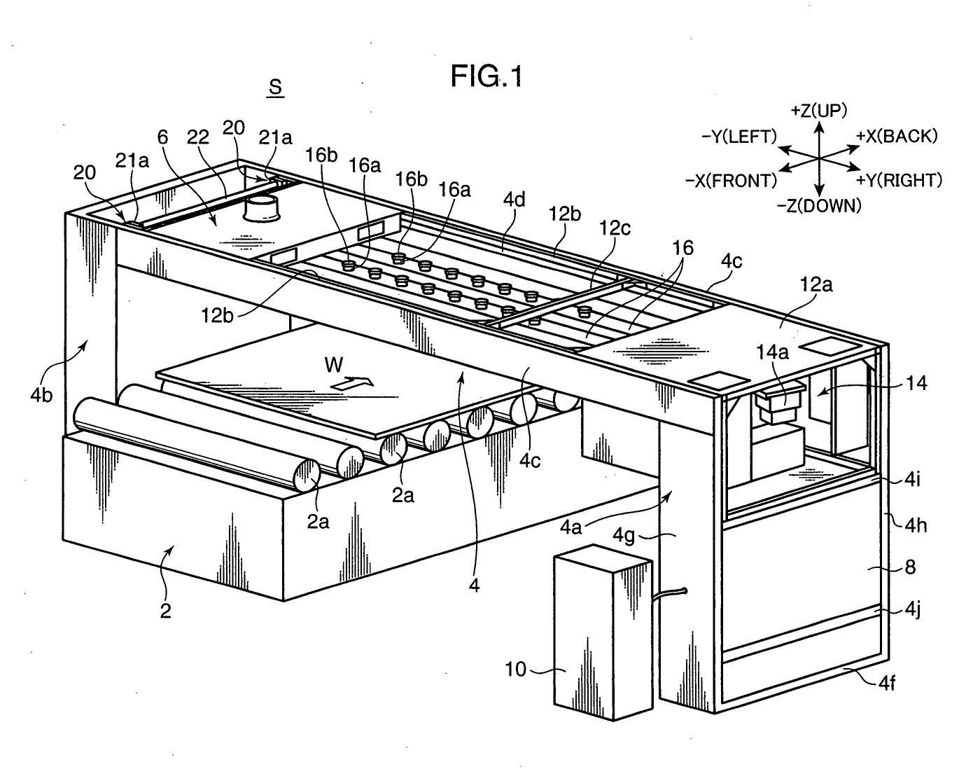

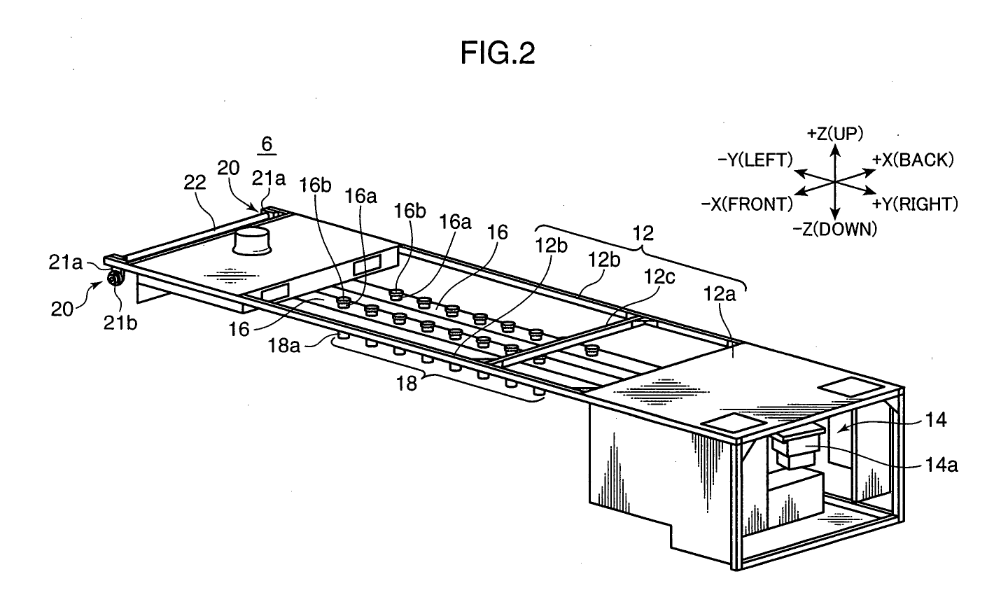

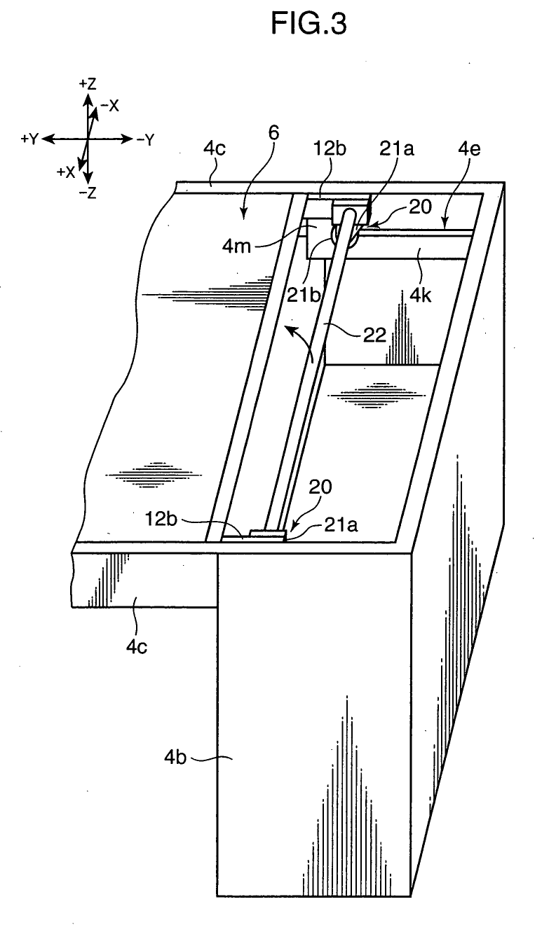

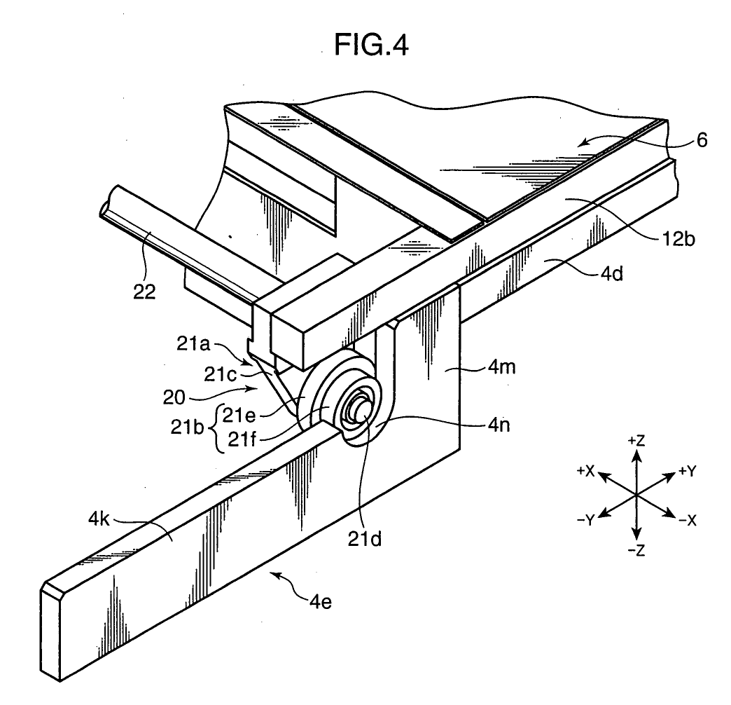

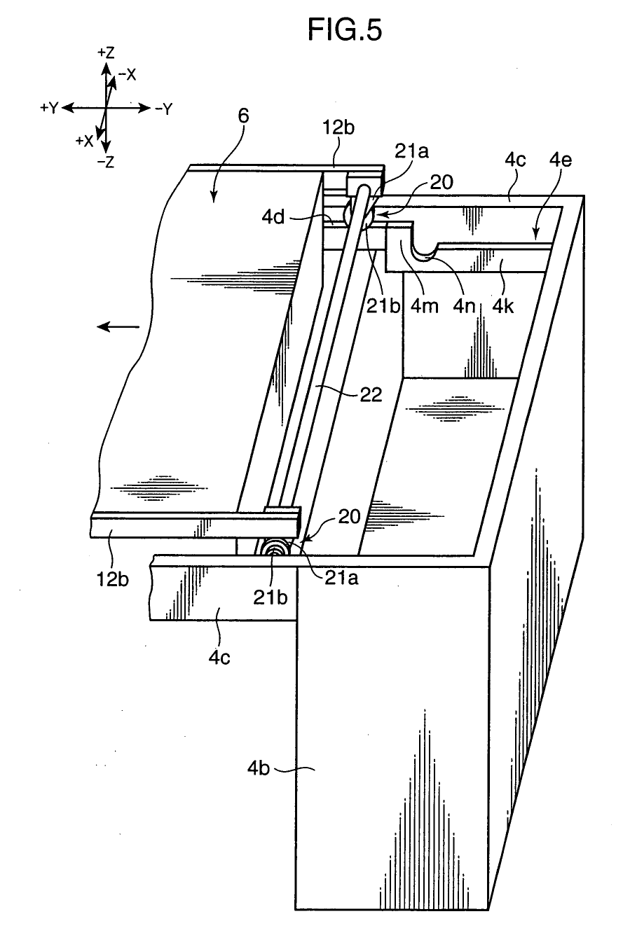

FIG. 1 is a perspective view showing a general structure of a workpiece processing apparatus S according to one embodiment of the present invention. FIG. 2 is a perspective view showing a plasma generator unit 6 of the workpiece processing apparatus S illustrated in FIG. 1. FIG. 3 is a fragmentary perspective view showing the workpiece processing apparatus S illustrated in FIG. 1, in a state when an engagement member 4e of a setup frame 4 and a roller member 21b of the plasma generator unit 6 are engaged with each other. FIG. 4 is an enlarged view showing a region where the engagement member 4e and the roller member 21b are engaged with each other, in FIG. 3. FIG. 5 is a fragmentary perspective view corresponding to FIG. 3, which shows a state after the engagement between the engagement member 4e of the setup frame 4 and the roller member 21b of the plasma generator unit 6 are released. The following description will be made on an assumption that the X-X direction, the Y-Y direction and the Z-Z direction in FIGS. 1 and 2, are defined, respectively, as “frontward/rearward direction”, “rightward/leftward direction” and “upward/downward direction”, and the −X direction, the +X direction, the −Y direction, the +Y direction, the −Z direction and the +Z direction, are defined, respectively, as “frontward direction”, “rearward direction”, “leftward direction”, “rightward direction”, “downward direction” and “upward direction”.

A workpiece processing apparatus S according to this embodiment is designed to plasmatize a given gas by an after-mentioned plasma generation section 18, and emit the plasmatized gas onto a target workpiece W so as to subject the workpiece W to various processings. As shown in FIG. 1, the workpiece processing apparatus S comprises a transport mechanism 2, a setup frame 4, a plasma generator unit 6, a control section 8 and an operation section 10.

The transport mechanism 2 is designed to transport the workpiece W to a position beneath the after-mentioned plasma generation section 18 of the plasma generator unit 6, while supporting the workpiece W. This transport mechanism 2 is installed to orient a transport direction thereof to the frontward/rearward direction, and provided with a plurality of transport rollers 2a arranged along the transport direction. The transport mechanism 2 includes driving means (not shown), and each of the transport rollers 2a is adapted to be driven by the driving means, so as to transport the workpiece W.

For example, the target workpiece W may include a flat-shaped substrate, such as a plasma display panel or a semiconductor substrate, and a circuit board having an electronic component mounted thereto. The target workpiece W may also include a non-flat-shaped component or combination component. In this case, a belt conveyer may be used instead of the transport rollers 2a.

The setup frame 4 is designed to set up the plasma generator unit 6 to allow the after-mentioned plasma generation section 18 of the plasma generator unit 6 to be located over the workpiece W supported by the transport mechanism 2, and formed in a portal shape which strides over the transport mechanism 2 in a widthwise direction (i.e., rightward/leftward direction). Specifically, the setup frame 4 includes a right leg member 4a, a left leg member 4b, a pair of horizontal connection members 4c, 4c, a guide rail 4d, and an engagement member 4e (see FIG. 3).

The right leg member 4a and the left leg member 4b are disposed, respectively, on right and left sides of the transport mechanism 2 to stand upwardly, and the setup frame 4 is supported relative to installation surface by the right and left leg members 4a, 4b.

The right leg member 4a has a bottom wall 4f, a front wall 4g, a rear wall 4h, and a pair of partition walls 4i, 4j. The bottom wall 4f is located at a bottom of the right leg member 4a, and disposed to extend horizontally. The front wall 4g is a member provided to extend vertically upwardly from a front edge of the bottom wall 4f, and the rear wall 4h is a member provided to extend vertically upwardly from a rear edge of the bottom wall 4f. The pair of partition walls 4i, 4j is mounted between respective opposed surfaces of the front wall 4g and the rear wall 4h, with a given distance therebetween in the upward/downward direction, in such a manner as to divide a space surrounded by the bottom wall 4f, the front wall 4g and the rear wall 4h, into three sub-spaces in the upward/downward direction. Each of the three sub-spaces is opened on both right and left sides thereof.

The left leg member 4b is formed in a box shape which has approximately the same dimensions as those of the right leg member 4a in the frontward/rearward direction.

Each of the pair of horizontal connection members 4c, 4c is formed and arranged to extend horizontally in the rightward/leftward direction, and connect the right leg member 4a and the left leg member 4b together at a position above the transport mechanism 2. The pair of horizontal connection members 4c, 4c are arranged in spaced-apart relation to each other by a given distance in the frontward/rearward direction, wherein one of the horizontal connection members 4c connects an upper end of the front wall 4g of the right leg member 4a and an upper end of a front wall of the left leg member 4b, and the other horizontal connection member 4c connects an upper end of the rear wall 4h of the right leg member 4a and an upper end of a rear wall of the left leg member 4b.

The guide rail 4d serves as a rail which is adapted, in a state when the plasma generator unit 6 is set in a setup position where the after-mentioned plasma generation section 18 is positioned over the workpiece W supported by the transport mechanism 2, to support opposite ends of the plasma generator unit 6 in the frontward/rearward direction, and, during an operation of drawing the plasma generator unit 6 out of the setup position, as will be described later, to allow an after-mentioned roller member 21b to be rolled thereon. In this embodiment, this guide rail 4d is composed of two guide sub-rails each mounted on a respective one of opposed side surfaces of the horizontal connection members 4c, 4c. Each of the guide sub-rails 4d, 4d is arranged at the same height to extend in parallel relation to the horizontal connection member 4c, i.e., extend horizontally in the rightward/leftward direction, over an entire longitudinal region of the horizontal connection member 4c (the guide sub-rail will hereinafter be referred to as “guide rail”, unless otherwise specified).

As shown in FIGS. 3 and 4, the engagement member 4e is designed to come into engagement with the roller member 21b of an after-mentioned movable support mechanism 20 so as to hold the plasma generator unit 6 in the setup position. In this embodiment, the engagement member 4e is composed of two engagement sub-members each mounted on a respective one of upper regions of opposed surfaces of the front and rear walls of the left leg member 4b. Each of the engagement sub-members 4e, 4e consists of an elongate plate which has a horizontal portion 4k extending horizontally in the rightward/leftward direction, and a protruding portion 4m protruding vertically upwardly from a right end of the horizontal portion 4k. Each of the engagement sub-members 4e, 4e is mounted in such a manner that a right edge surface of the protruding portion 4m is in contact with a left edge surface of a corresponding one of the guide rails 4d, 4d, and an upper edge surface of the protruding portion 4m is in flush relation with an upper edge surface of the corresponding guide rail 4d (the engagement sub-member will hereinafter be referred to as “engagement member”, unless otherwise specified).

Further, the engagement member 4e has an arc-shaped concave portion 4n provided in an upper edge surface of the horizontal portion 4k at a position adjacent to the protruding portion 4m. This concave portion 4n is designed to allow a small-diameter portion 21f of the roller member 21b of the after-mentioned movable support mechanism 20 to be fitted therein when the plasma generator unit 6 is set in the setup position, and formed in a size corresponding to the small-diameter portion 21f of the roller member 21b.

The plasma generator unit 6 is a device capable of generating plasma at normal temperatures and pressures by means of microwave. As shown in FIG. 1, the plasma generator unit 6 is disposed to orient a longitudinal direction thereof to the rightward/leftward direction, i.e., to extend in a direction orthogonal to the direction for transporting the workpiece W by the transport mechanism 2, in a position above the transport mechanism 2. The plasma generator unit 6 is mounted to the setup frame 4 in a manner capable of being drawn out of the setup position rightwardly in a horizontal direction.

Specifically, as shown in FIG. 2, the plasma generator unit 6 comprises a body frame 12, a power supply section 14, a pair of waveguides 16, 16, a plasma generation section 18, and a pair of movable support mechanisms 20, 20, and a lifting member 22.

The body frame 12 serves as a frame of the plasma generator unit 6, and has a power-supply-section receiving member 12a, a pair of support frame members 12b, 12b, and a connection bar 12c (hereinafter referred to as “connection member”).

The power-supply-section receiving member 12a is a box-shaped member provided at a right end of the plasma generator unit 6, and formed to receive therein the power supply section 14.

The pair of support frame members 12b, 12b are designed to support the plasma generator unit 6 relative to the guide rail 4d of the setup frame 4 in the state when the plasma generator unit 6 is set in the setup position. The support frame members 12b, 12b are disposed to define front and rear edges of the plasma generator unit 6, respectively, and extend in parallel relation to each other and horizontally in the rightward/leftward direction.

The connection member 12c is disposed to bridge between respective intermediate regions of the support frame members 12b, 12b so as to integrate the support frame members 12b, 12b together.

The power supply section 14 is designed to supply a microwave power to a plasma generation section 18, and received in the power-supply-section receiving member 12a at the right end of the plasma generator unit 6. This power supply section 14 is provided with a microwave generator 14a operable to generate a microwave, and adapted to emit a microwave having a given wavelength, e.g., about 2.5 GHz, generated by the microwave generator 14a, into the waveguides 16, 16.

Each of the pair of waveguides 16, 16 is designed to allow the microwave generated by the microwave generator 14a to propagate therethrough in a longitudinal direction thereof toward the plasma generation section 18. For example, the waveguide, 16 is made of a nonmagnetic metal (e.g., aluminum), and formed as a long tube-like member having a rectangular shape in section. The waveguides 16, 16 are disposed to extend horizontally in the rightward/leftward direction with a given distance therebetween in the frontward/rearward direction. The waveguide 16 has a right end for introducing therein the microwave emitted from the microwave generator 14a.

The waveguide 16 has a top wall provided with a plurality of replacement ports 16a for replacement of respective inner conductors of after-mentioned plasma generation nozzles 18a at respective positions corresponding to the after-mentioned plasma generation nozzles 18a. Each of the replacement ports 16a has an upper opening closed by a cap 16b. Thus, in a replacement task for the inner conductor, the cap 16b is detached, and the inner conductor is replaced through the replacement port 16a.

The plasma generation section 18 is designed to plasmatize a given gas supplied thereto, and made up of two groups of plasma generation nozzles 18a each provided to protrude from a bottom wall (surface opposed to the workpiece W) of a corresponding one of the waveguides 16, 16, and arranged in the rightward/leftward direction at given intervals to form a line.

Each of the plasma generation nozzles 18a is provided, but not shown, with an inner conductor and an outer conductor. The inner conductor is composed of a bar-shaped conductor made of an electrically-conductive metal, and disposed such that an upper end thereof penetrates through the bottom wall of the waveguide 16 and protrudes into an inner space of the waveguide 16. The inner waveguide and the waveguide 16 are electrically isolated from each other. The outer conductor is composed of an generally cylindrical-shaped conductor, and disposed to surround around the inner conductor. The outer conductor is in electrical conduction relation with (i.e., has the same potential as that of) the waveguide 16. Further, a given processing gas, such as oxygen gas or oxygen-based gas (e.g., air) is supplied into a space between the outer and inner conductors.

When a microwave power is received by the upper end of the inner conductor to supply a power to the inner conductor, an electric field-concentrated region is formed in a vicinity of respective lower ends of the inner and outer conductors. In this state, when the processing gas is supplied into the space between the inner and outer conductors, the processing gas is excited to generate a plasma around the lower end of the inner conductor. According to a stream of the supplied gas, the processing gas plasmatized in this manner is emitted from a lower end of the plasma generation nozzle 18a in the form of a plume. Based on the plasmatized and emitted gas, the work W is subjected to a given processing, such as an organic-matter decomposition or removal processing, a resist-film removal processing, a surface cleaning processing, a surface modification processing, or a thin-film formation processing.

The pair of movable support mechanisms 20, 20 are designed to support the plasma generator unit 6 relative to the guide rails 4d, 4d while being moved in a longitudinal direction of the guide rails 4d, 4d, during the operation of drawing the plasma generator unit 6 out of the setup position.

Specifically, as shown in FIG. 4, the movable support mechanisms 20, 20 are mounted to respective left ends of the support frame members 12b, 12b of the body frame 12. Each of the movable support mechanisms 20, 20 comprises an attaching member 21a and a roller member 21b. The attaching member 21a is designed to attach the roller member 21b to the body frame 12. The anchor member 21a is mounted to an inner (when viewed in the widthwise direction of the plasma generator unit 6) side surface of the left end of a corresponding one of the support frame members 12b, 12b. The attaching member 21a has a base portion 21c protruding downwardly, and a shaft portion 21d protruding from a lower end of the base portion 21c outwardly in the widthwise direction of the plasma generator unit 6.

The roller member 21b is rotatably attached to the shaft portion 21d of the attaching member 21a. In the movable support mechanism 20, the roller member 21b is adapted, during the operation of drawing the plasma generator unit 6 out of the setup position, to support the plasma generator unit 6 relative to the guide rail 4d, while being rolled on the guide rail 4d. The roller member 21b has a large-diameter portion 21e, and a small-diameter portion 21f formed and arranged in integral and coaxial relation with the large-diameter portion 21e. The small-diameter portion 21f is provided to protrude from the large-diameter portion 21e outwardly in the widthwise direction of the plasma generator unit 6.

When the plasma generator unit 6 is set in the setup position, the small-diameter portion 21f of the roller member 21b is fitted into the concave portion 4n of a corresponding one of the engagement members 4e, 4e, and thereby the roller member 21b is engaged with the engagement member 4e to allow the plasma generator unit 6 to be held in the setup position. That is, in a state when the small-diameter portion 21f of the roller member 21b is fitted in the concave portion 4n of the engagement member 4e, a horizontal movement of the plasma generator unit 6 is restricted so that the plasma generator unit 6 is temporarily fixed in the setup position.

Then, in the operation of drawing the plasma generator unit 6 out of the setup position, the left end of the plasma generator unit 6 is lifted upwardly to disengage the small-diameter portion 21f of the roller member 21b from the concave portion 4n of the engagement member 4e, and then placed on the guide rail 4d. In this state, the plasma generator unit 6 can be drawn relative to the setup frame 4 by pulling or pushing the plasma generator unit 6 rightwardly in a horizontal direction the plasma generator unit 6, with the aid of rolling of the small-diameter portion 21f of the roller member 21b on the guide rail 4d.

The lifting member 22 is formed as a bar-shaped member disposed to bridge between the respective base portions 21c, 21c of the attaching members 21a, 21a and extend horizontally in the frontward/rearward direction. During an operation of disengaging the roller member 21b from the concave portion 4n of the engagement member 4e, an operator can grip the lifting member 22 to lift the left end of the plasma generator unit 6 upwardly.

As shown in FIG. 1, the control section 8 is installed in the sub-space between the partition walls 4i, 4j of the right leg member 4a of the setup frame 4, and designed to control the plasma generator unit 6 and other sections. For example, the control section 8 is operable to control a microwave generating operation of the microwave generator 14a, a flow rate of the processing gas to be supplied to the plasma generation nozzles 18a of the plasma generation section 18, and an operation of a drive motor for driving the transport rollers 2a of the transport mechanism 2, and interlockingly control respective operations of the plurality of sections constituting the workpiece processing apparatus S.

The operation section 10 is designed to provide a given operational signal to the control section 8. The operation section 10 is installed at a position adjacent to the right leg member 4a, and electrically connected to the control section 8.

An operation to be performed during a maintenance task for the plasma generation section 18 will be described below.

In the state when the plasma generator unit 6 is set in the setup position, i.e., the roller member 21b is fitted in the concave portion 4n of the engagement member 4e (the state illustrated in FIG. 3), an operator firstly grips the lifting member 22 to lift the left end of the plasma generator unit 6 upwardly and push the plasma generator unit 6 in the rightward (+Y) direction. Through this operation, as shown in FIG. 5, the small-diameter portion 21f (see FIG. 4) of the roller member 21b is disengaged from the concave portion 4n of the engagement member 4e, and placed on the guide rail 4d.

As a result of the above pushing operation, the power-supply-section receiving member 12a of the plasma generator unit 6 protrudes from the right leg member 4a of the setup frame 4, in the rightward (+Y) direction. Thus, the protruded power-supply-section receiving member 12a is placed on and supported by a dolly or the like. Then, the plasma generator unit 6 is further drawn horizontally in the rightward direction. During this operation, the roller member 21b of the movable support mechanism 20 supports the left end of the plasma generator unit 6 while being rolled on the guide rail 4d. Thus, in the operation of drawing the plasma generator unit 6 out of the setup position, the plasma generator unit 6 can be drawn by a relatively small force, with the aid of the rolling of the roller member 21b.

When the plasma generator unit 6 is drawn out of the setup position over the transport mechanism 2, i.e., into a position convenient for the maintenance task, the drawing operation is stopped to perform the maintenance task for the plasma generation section 18, such as replacement of the plasma generation nozzle 18a or inspection of the plasma generation section 18.

After completion of the maintenance task, in a manner the reverse of the above operation, the plasma generator unit 6 is drawn relative the setup frame 4 until it is set in the setup position. When the plasma generator unit 6 is moved to the setup position, the small-diameter portion 21f of the roller member 21b of the movable support mechanism 20 is fitted into the concave portion 4n from the guide rail 4d through the upper edge surface of the protruding portion 4m of the engagement member 4e. Thus, the engagement member 4e and the roller member 21b are engaged with each other to allow the plasma generator unit 6 to be held in the setup position.

In the above manner, the maintenance task for the plasma generation section 18 in the workpiece processing apparatus S is performed.

As described above, in the workpiece processing apparatus according to the above embodiment, the plasma generator unit 6 is mounted to the setup frame 4 in a manner capable of being drawn out of the setup position where the plasma generation section 18 is located over the workpiece W supported by the transport mechanism 2, in a horizontal direction orthogonal to the direction for transporting the workpiece W by the transport mechanism 2. Thus, after the plasma generator unit 6 is drawn to a position where the plasma generation section 18 is located out of the setup position over the transport mechanism 2, the maintenance task for the plasma generation section 18 can be performed without being obstructed by the transport mechanism 2. This makes it possible to facilitate the maintenance task for the plasma generation section 18.

The workpiece processing apparatus according to the above embodiment includes the movable support mechanism 20 which is adapted, during the operation of drawing the plasma generator unit 6 out of the setup position, to support the left end of the plasma generator unit 6 relative to the guide rail 4d of the setup frame 4 while being moved on the guide rail 4d. A combination of the guide rail 4d and the movable support mechanism 20 can make up a structure which allows the plasma generator unit 6 to be readily drawn out of the setup position in the horizontal direction. This makes it possible to facilitate drawing the plasma generator unit 6 during the maintenance task, as compared with a workpiece processing apparatus devoid of the guide rail 4d and the movable support mechanism 20, so as to further facilitate the maintenance task for the plasma generation section 18.

In the workpiece processing apparatus according to the above embodiment, the movable support mechanism 20 includes the roller member 21b which is adapted, during the operation of drawing the plasma generator unit 6 out of the setup position, to support the plasma generator unit 6 relative to the guide rail 4d while being rolled on the guide rail 4d. Thus, the plasma generator unit 6 can be drawn by a relatively small force, with the aid of the rolling of the roller member 21b. This makes it possible to further facilitate drawing the plasma generator unit 6 during the maintenance task.

In the workpiece processing apparatus according to the above embodiment, the setup frame 4 is provided with the engagement member 4e, which is adapted to come into engagement with the roller member 21b of the movable support mechanism 20 so as to hold the plasma generator unit 6 in the setup position. Thus, although the plasma generator unit 6 is adapted to be generally drawable, when the plasma generator unit 6 is set in the setup position, the engagement member 4e can prevent a displacement of the plasma generator unit 6 from the setup position. This makes it possible to prevent a displacement of the plasma generator unit 6 from the setup position while facilitating the maintenance task for the plasma generation section 18.

In the workpiece processing apparatus according to the above embodiment, the plasma generator unit 6 is provided with the power supply section 14 operable to supply a microwave power to the plasma generation section 18, and the setup frame 4 is provided with the control section 8 operable to control the plasma generator unit 6. Thus, as compared with a structure where the plasma generator unit 6 is provided with both the power supply section 14 and the control section 8, a weight of the plasma generator unit 6 can be reduced. This makes it possible to reduce a workload during the operation of drawing the plasma generator unit 6 out of the setup position or the operation of inserting the plasma generator unit 6 into the setup frame 4.

It should be understood that the embodiment disclosed in this specification is not meant to be construed in a limiting sense, but is only for illustrative purposes in all respects. The scope of the present invention should not be determined by the description about the embodiment but by the appended claims, and the invention is intended to cover alternatives, modifications, changes and legal equivalents, which may be included within the appended claims.

For example, while the above embodiment has been described based on an example where the support section adapted to support the workpiece W beneath the plasma generation section 18 comprises the transfer mechanism 2, the present invention is not limited to this structure. Specifically, the present invention may also be implemented under a condition that the plasma is emitted onto the workpiece W supported by a support section adapted to support the workpiece W beneath the plasma generation section 18, in a fixed, immovable or stationary manner.

Further, the movable support mechanism 20 employed in the above embodiment is provided with the roller member 21b adapted to support the plasma generator unit 6 relative to the guide rail 4d while being rolled on the guide rail 4d. Alternatively, a movable support mechanism having any other suitable structure may be employed. For example, a movable support mechanism adapted to support the plasma generator unit 6 relative to the guide rail 4d while being slid on the guide rail 4d in the longitudinal direction thereof may be employed.

As above, the present invention may be summarized as follows.

A workpiece processing apparatus of the present invention comprises: a plasma generator unit including a plasma generation section operable to plasmatize a given gas supplied thereto, and emit the plasmatized gas therefrom; and a support section adapted to support a target workpiece in a position beneath the plasma generation section, wherein the plasmatized gas is emitted onto the workpiece to carry out a given processing. The workpiece processing apparatus further includes a setup frame adapted to set up the plasma generator unit to allow the plasma generation section to be located over the workpiece. The plasma generator unit is mounted to the setup frame in a manner capable of being drawn out of a setup position where the plasma generation section is positioned over the workpiece, in a horizontal direction.

In the workpiece processing apparatus of the present invention, the plasma generator unit can be drawn out of the setup position where the plasma generation section is positioned over the workpiece, in the horizontal direction. Thus, after drawing the plasma generator unit to a position where the plasma generation section is located out of the setup position over the support section which supports the workpiece, a maintenance task for the plasma generation section can be performed without being obstructed by the support section. This makes it possible to facilitate the maintenance task for the plasma generation section.

Preferably, in the workpiece processing apparatus of the present invention, the setup frame includes a guide rail extending horizontally, and the plasma generator unit includes a movable support mechanism adapted, during an operation of drawing the plasma generator unit out of the setup position, to support the plasma generator unit relative to the guide rail while being moved on the guide rail.

According to this feature, a combination of the guide rail and the movable support mechanism can make up a structure which allows the plasma generator unit to be readily drawn out of the setup position in the horizontal direction. This makes it possible to facilitate drawing the plasma generator unit during the maintenance task, as compared with a workpiece processing apparatus devoid of the guide rail and the movable support mechanism, so as to further facilitate the maintenance task for the plasma generation section.

In this case, the setup frame preferably includes an engagement member adapted to come into engagement with the movable support mechanism so as to hold the plasma generator unit in the setup position.

According to this feature, although the plasma generator unit is adapted to be generally drawable, when the plasma generator unit is set in the setup position, the engagement member can prevent a displacement of the plasma generator unit from the setup position. This makes it possible to prevent a displacement of the plasma generator unit from the setup position while facilitating the maintenance task for the plasma generation section.

Preferably, in the above workpiece processing apparatus, the plasma generator unit includes a pair of support frame members extending in the drawing direction, wherein each of the support frame members is designed such that a lower surface thereof comes into contact with an upper surface of the guide rail when the plasma generator unit is in the setup position.

According to this feature, when the plasma generator unit is placed on the setup frame and set in the setup position, the support frame members of the plasma generator unit and the guide rail of the setup frame is in contact with each other. This makes it possible to stabilize a setup state of the plasma generator unit relative to the setup frame.

Preferably, in the above workpiece processing apparatus, the movable support mechanism includes a base portion extending downwardly from a trailing end of each of the support frame members in the drawing direction, and a roller member rotatably provided to the base portion, wherein the engagement member of the setup frame comprises a concave portion concaved downwardly relative to the guide rail, and the roller member is adapted to be received in and held by the concave portion, in the setup position.

According to this feature, the roller member of the plasma generator unit set in the setup position is fitted into the concave portion of the setup frame from thereabove. This makes it possible to further stabilize the setup state of the plasma generator unit relative to the setup frame.

Preferably, in the above workpiece processing apparatus, the plasma generator unit includes a lifting member which is provided in a vicinity of the trailing ends of the support frame members, and adapted to be lifted upwardly so as to allow the plasma generator unit to be disengaged from the setup frame.

According to this feature, through an operation of lifting the lifting member upwardly, an operator can disengage the plasma generator unit from the setup frame in a relatively easy manner.

Preferably, in the above workpiece processing apparatus, the lifting member is adapted to be lifted upwardly so as to allow the roller member to be disengaged from the concave portion, and then moved in the drawing direction so as to allow the roller member to be placed on the guide rail and rolled on the guide rail, whereby the plasma generator unit is allowed to be drawn relative to the setup frame in the horizontal direction.

According to this feature, through an operation of lifting the lifting member upwardly and approximately simultaneously displacing (moving) the lifting member in the drawing direction, an operator can place the roller member on the guide rail. This makes it possible to facilitate the operation of disengaging the plasma generator unit from the setup frame.

Preferably, in the above workpiece processing apparatus, the roller member includes a large-diameter portion, and a small-diameter portion formed in coaxial and integral relation with the large-diameter portion, wherein the small-diameter portion and the large-diameter portion are configured, respectively, to come into rollable contact with the upper surface of the guide rail and to come into contact with a widthwise inner surface of the guide rail, when the plasma generator unit is drawn relative to the setup frame in the horizontal direction.

According to this feature, during the operation of disengaging the plasma generator unit from the setup frame, the small-diameter portion of the roller member is rollingly moved on the guide rail to facilitate moving the plasma generator unit in the drawing direction. In addition, during the movement, the large-diameter portion of the roller member is kept in contact with the widthwise inner surface of the guide rail. This makes it possible to stably perform the operation of moving the plasma generator unit in the drawing direction.

Preferably, in the workpiece processing apparatus of the present invention, the plasma generator unit is provided with a power supply section operable to supply a microwave power to the plasma generation section, and the setup frame is provided with a control section operable to control the plasma generator unit.

According to this feature, as compared with a structure where the plasma generator unit is provided with both the power supply section and the control section, a weight of the plasma generator unit can be reduced. This makes it possible to reduce a workload during the operation of drawing the plasma generator unit out of the setup position or the operation of inserting the plasma generator unit into the setup frame.

Preferably, in the workpiece processing apparatus of the present invention, the support section comprises a transport mechanism operable to transport the workpiece to a position beneath the plasma generation section while supporting the workpiece, and the plasma generator unit is mounted to the setup frame in a manner capable of being drawn out of the setup position in a direction intersecting with a direction for transporting the workpiece by the transport mechanism.

In cases where the support section comprises a transport mechanism operable to transport the workpiece to a position beneath the plasma generation section, as in the above workpiece processing apparatus, the plasma generator unit can be drawn in the direction intersecting with the direction for transporting the workpiece, to perform the maintenance task for the plasma generator unit, in a position out of the setup position over the transfer mechanism. Thus, according the above feature, in the workpiece processing apparatus provided with the transport mechanism operable to transport the workpiece to a position beneath the plasma generation section, the maintenance task for the plasma generator unit can be performed in an easy manner.

As mentioned above, the workpiece processing apparatus of the present invention makes it possible to facilitate the maintenance task for the plasma generator unit.

This application is based on Japanese Patent Application Serial No. 2007-139174, filed in Japan Patent Office on May 25, 2007, the contents of which are hereby incorporated by reference.

Although the present invention has been fully described by way of example with reference to the accompanying drawings, it is to be understood that various changes and modifications will be apparent to those skilled in the art. Therefore, unless otherwise such changes and modifications depart from the scope of the present invention hereinafter defined, they should be construed as being included therein.

What is claimed is:

1. A workpiece processing apparatus comprising:
a plasma generator unit including a plasma generation section operable to plasmatize a given gas supplied thereto, and emit said plasmatized gas therefrom;
a support section adapted to support a target workpiece, in a position beneath said plasma generation section wherein said plasma generator unit carries out a given processing by emitting said plasmatized gas onto said workpiece; and
a setup frame adapted to set up said plasma generator unit to allow said plasma generation section to be located over said workpiece,
wherein said plasma generator unit is mounted to said setup frame in a manner capable of being drawn out of a setup position where said plasma generation section is positioned over said workpiece, in a horizontal direction.

2. The workpiece processing apparatus according to claim 1, wherein:
said setup frame includes a guide rail extending horizontally; and
said plasma generator unit includes a movable support mechanism adapted, during an operation of drawing said plasma generator unit out of said setup position, to support said plasma generator unit relative to said guide rail while being moved on said guide rail.

3. The workpiece processing apparatus according to claim 2, wherein said setup frame includes an engagement member adapted to come into engagement with said movable support mechanism so as to hold said plasma generator unit in said setup position.

4. The workpiece processing apparatus according to claim 3, wherein said plasma generator unit includes a pair of support frame members extending in said drawing direction, each of said support frame members being designed such that a lower surface thereof comes into contact with an upper surface of said guide rail when said plasma generator unit is in said setup position.

5. The workpiece processing apparatus according to claim 4, wherein said movable support mechanism includes a base portion extending downwardly from a trailing end of each of said support frame members in said drawing direction, and a roller member rotatably provided to said base portion, wherein:
said engagement member of said setup frame being formed with a concave portion concaved downwardly relative to said guide rail; and
said roller member is adapted to be received in and held by said concave portion, in said setup position.

6. The workpiece processing apparatus according to claim 5, wherein said plasma generator unit has a lifting member which is provided in a vicinity of said trailing ends of said support frame members, and is adapted to be lifted upwardly so as to allow said plasma generator unit to be disengaged from said setup frame.

7. The workpiece processing apparatus according to claim 6, wherein said lifting member is adapted to be lifted upwardly so as to allow said roller member to be disengaged from said concave portion, and then moved in said drawing direction so as to allow said roller member to be placed on said guide rail and rolled on said guide rail, whereby said plasma generator unit is allowed to be drawn relative to said setup frame in said horizontal direction.

8. The workpiece processing apparatus according to claim 7, wherein said roller member includes a large-diameter portion, and a small-diameter portion formed in coaxial and integral relation with said large-diameter portion, said small-diameter portion and said large-diameter portion being configured, respectively, to come into rollable contact with said upper surface of said guide rail and to come into contact with a widthwise inner surface of said guide rail, when said plasma generator unit is drawn relative to said setup frame in said horizontal direction.

9. The workpiece processing apparatus according to claim 1, wherein:
said plasma generator unit is provided with a power supply section operable to supply a microwave power to said plasma generation section; and
said setup frame is provided with a control section operable to control said plasma generator unit.

10. The workpiece processing apparatus according to claim 1, wherein:
said support section includes a transport mechanism operable to transport said workpiece to a position beneath said plasma generation section while supporting said workpiece; and
said plasma generator unit is mounted to said setup frame in a manner capable of being drawn out of said setup position in a direction intersecting with a direction for transporting said workpiece by said transport mechanism.
